(19) United States
(12) Patent Application Publication
(10) Pub. No.: US 2021/0333706 A1
(43) Pub. Date: Oct. 28, 2021

(54) MASK AND METHOD FOR TESTING QUALITY OF MASK

(71) Applicant: CHANGXIN MEMORY TECHNOLOGIES, INC., Hefei City (CN)

(72) Inventor: Mei-Li Wang, Hefei (CN)

(21) Appl. No.: 17/371,331

(22) Filed: Jul. 9, 2021

Related U.S. Application Data
(63) Continuation of application No. PCT/CN2021/084065, filed on Mar. 30, 2021.

(30) Foreign Application Priority Data
Apr. 10, 2020 (CN) 202010279765.9

(51) Int. Cl. G03F 1/44; G03F 1/84

(52) U.S. Cl. CPC G03F 1/44; G03F 1/84

(57) ABSTRACT

The present disclosure provides a mask and a method for testing a quality of the mask, the mask includes a mask exposure region and a region other than mask exposure region. The mask exposure region is provided with a mask pattern. The region other than mask exposure region is provided with a test area. The test area includes at least one test mark. A deviation between a design size and an actual size of the each test mark is used to determine the quality of the mask.

### CROSS-REFERENCE TO RELATED APPLICATION

This is a continuation application of International Patent Application No. PCT/CN2021/084065, filed on Mar. 30, 2021, which claims priority to Chinese Patent Application No. 202010279765.9, filed on Apr. 10, 2020 and entitled “Mask and Mask Quality Test Method”. The disclosures of International Patent Application No. PCT/CN2021/084065 and Chinese Patent Application No. 202010279765.9 are incorporated by reference herein in their entireties.

### TECHNICAL FIELD

The present disclosure relates to the technical field of semiconductor, and particularly to a mask and a method for testing a quality of mask.

### BACKGROUND

A photolithography process is a key process for fabricating semiconductor devices and integrated circuit micro patterns structures. Therefore, a quality of the photolithography process directly affects a stability and improvement of parameters such as a yield, reliability, device performance and service life of the semiconductor devices.

A mask is a device used to define a pattern in a chip design onto a wafer, and a quality of the mask directly affects a quality of the wafer and even the yield of the finished semiconductor device. With a continuous development of microelectronic processing technology, a pattern on the mask becomes more complex and larger, a line of the pattern is required to be thinner, and a requirement on mask performance and precision becomes higher. However, due to an influence of a process environment and a formation of raw materials or other factors, the mask pattern may be distorted, that is, quality problems of the mask appear frequently, and the mask needs to be remanufactured, which results in a waste of cost and delay in the photolithographic process.

### SUMMARY

Embodiments of the present disclosure provide a mask and a method for testing a quality of the mask, to lower a risk of remanufacturing the mask due to the quality problems that are easily appear on the mask.

In a first aspect, an embodiment of the present disclosure provides a mask including a mask exposure region and a region other than mask exposure region.

The mask exposure region is provided with a mask pattern.

The mask non-exposure area is provided with a test area. The test area includes at least one test mark; a quality of the mask is determined from a deviation between a design size and an actual size of each test mark.

In a second aspect, an embodiment of the present disclosure further provides a method for testing a quality of the mask according to any embodiment of the present disclosure including:

measuring an actual size of the test mark of a test area of a region other than mask exposure region;

obtaining a deviation between the actual size and a design size for the test mark;

in response to the deviation greater than an allowable error threshold value, determining that the mask is unqualified; in response to the deviation less than the allowable error threshold value, determining that the mask is qualified.

### BRIEF DESCRIPTION OF THE DRAWINGS

FIG. 1 is a schematic view of a mask according to an embodiment of the present disclosure;

FIG. 2 is an enlarged view of a test area A of the mask of FIG. 1;

FIG. 3 is another enlarged schematic view of the test area A of the mask of FIG. 1;

FIG. 4 is another enlarged schematic view of the test area A of the mask of FIG. 1;

FIG. 5 is another enlarged schematic view of the test area A of the mask of FIG. 1;

FIG. 6 is another enlarged schematic view of the test area A of the mask of FIG. 1;

FIG. 7 is another enlarged schematic view of the test area A of the mask of FIG. 1;

FIG. 8 is another enlarged schematic view of the test area A of the mask of FIG. 1;

FIG. 9 is a schematic flow chart of a method for testing the quality of the mask according to an embodiment of the present disclosure;

FIG. 10 is a schematic flow chart of another method for testing the quality of the mask according to an embodiment of the present disclosure;

FIG. 11 is a schematic flow chart of another method for testing the quality of the mask according to an embodiment of the present disclosure;

FIG. 12 is a schematic flow chart of another method for testing the quality of the mask according to an embodiment of the present disclosure.

### DETAILED DESCRIPTION

The present disclosure will be further described in detail below with reference to the accompanying drawings and embodiments. It is to be understood that the specific embodiments described herein are merely used to illustrate the present disclosure and are not used to limit the present disclosure. It is further to be noted that, for ease of description, only a part of, but not all, structures related to the present disclosure are shown in the accompanying drawings.

In the related art, when a manufacturing quality of a mask used in a photolithography process is unqualified, the accuracy of the mask is easily too low, which affects the yield of a final product, and even the mask needs to be remanufactured, thereby causing a waste of cost. To solve the above problem, an embodiment of the present disclosure provides a mask including a mask exposure region and a region other than mask exposure region.

The mask exposure area is provided with a mask pattern.

The region other than mask exposure region is provided with a test area. The test area includes at least one test mark. A deviation between a design size and an actual size of each test mark is used to determine a quality of the mask.

In an embodiment of the present disclosure, the mask includes the mask exposure region and the region other than mask exposure region. The mask exposure region is formed with a mask pattern for forming the exposure pattern on a wafer. The region other than mask exposure region is provided with a test area for testing the quality of the mask. Specifically, the test area is provided with at least one test mark, and each of the test marks does not form the exposure pattern on the wafer, and is only used for testing a quality problem due to a material, a manufacturing process, or other factors of the mask through a distortion of the test marks during the forming process, and the distortion degree can be known by comparing the actual size and the design size of the test marks. The mask and the method for testing the quality of the mask provided by the embodiment of the present disclosure can be used to know the manufacturing quality of the mask, for example, whether the mask is qualified, thereby the stability of the mask is enhanced, the stability of the mask pattern is further ensured, the accuracy of the mask is enhanced, the yield of the wafer or even the final product is enhanced, and the risk of remanufacturing of the mask is reduced, and the cost waste in the photolithographic process is prevented.

The above is the core of the present disclosure, and the technical solution in the embodiments of the present disclosure will be clearly and completely described below in connection with the accompanying drawings in the embodiments of the present disclosure. Based on the embodiments of the present disclosure, all other embodiments obtained by a person of ordinary skill in the art without involving any inventive effort are within the scope of protection of the present disclosure.

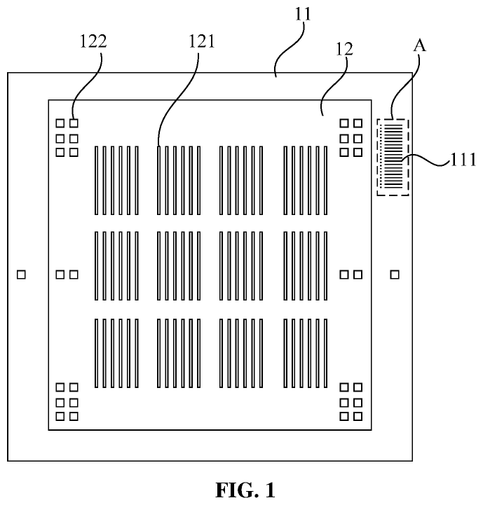

FIG. 1 is a schematic view of a mask according to an embodiment of the present disclosure. As shown in FIG. 1, the mask includes a mask exposure region 12 and a region 11 other than mask exposure region. The mask exposure region 12 is provided with a mask pattern 121, and the mask pattern 121 is formed by hollowing a pattern on a mask body. After an exposure and an etching are performed on the wafer through the mask, the mask pattern 121 is formed on the wafer to complete a pattern transfer process. In addition, the mask exposure region 12 may be provided with an alignment mark 122 which is formed on the wafer or photoresist to complete the alignment task. For example, the alignment mark 122 may include an exposure alignment mark, a thin film alignment mark, and the like, in which the exposure alignment mark is configured for the alignment of a photoetching machine and the mask, and the thin film alignment mark is configured for the alignment of the film layers formed on the wafer. The alignment mark ensures the fabrication accuracy of the wafer and improves the yield of final product.

In the present embodiment, in order to avoid the accuracy of the mask being affected by the quality of the mask, the region 11 other than mask exposure region is provide with a test area A, and the test area A is provided with a test mark 111 which is different from the mask pattern 121 and the alignment mark 122. The test mark 111 does participate in the formation of the exposure pattern, so that the test mark 111 does not affect the mask pattern 121 and does not cause a pattern defect on the wafer. That is, the test mark 111 only tests the quality problem of the mask caused by the mask material or the manufacturing process. Therefore, before the exposure is performed and even before the mask pattern 121 is formed on the mask, the quality of the mask is tested in advance by the test mark 111, thereby avoiding the problem that the accuracy of the mask is low and even the mask pattern 121 is remanufactured. Specifically, the distortion generated during the mask pattern forming process can be evaluated by a difference between the actual size and the design size of the test mark 111, and thus it is possible to predict the distortion to be generated on the mask pattern and determine whether the mask plate is qualified. In some embodiments, multiple judgment levels and criteria may be provide to classify a quality level of the mask into several levels such as unqualified, qualified, good or excellent, to further control the quality of the mask to meet different requirements of the accuracy of the mask.

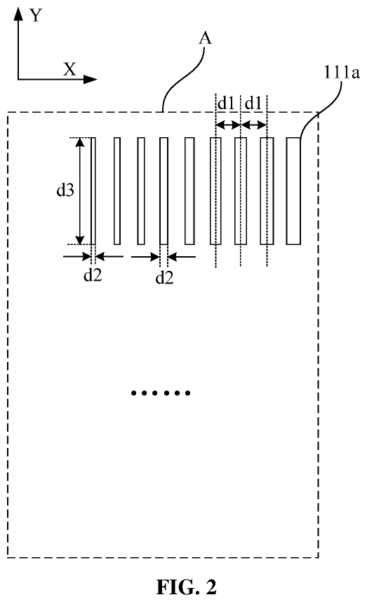

FIG. 2 is an enlarged view of the test area A of the mask of FIG. 1. In some embodiments, the test area A may include multiple first test marks 111a arranged sequentially along a first direction X. Each two adjacent first test marks 111a is arranged with an identical spacing between midlines of the two adjacent first test marks 111a. Each of the midlines extends along a second direction Y perpendicular to the first direction X. Widths d2 of respective first test marks 111a arranged in the first direction X are gradually increased or gradually decreased along the first direction X.

The present embodiment may provide with multiple first test marks 111a to facilitate the measurement of the stability of the mask. The first test marks 111a may also be sequentially arranged along any one direction in order to facilitate measurement of the stability in this direction. In the present embodiment, the first direction X may be selected as an arrangement direction of the first test marks 111a, and each two adjacent first test marks 111a may be arranged with the identical spacing, that is, each two adjacent first test marks 111a is arranged with the identical spacing between midlines of the two adjacent first test marks, and the midline is a straight line passing through a midpoint of the first test mark 111a. As shown in FIG. 2, an extension direction of the midlines is the second direction Y perpendicular to the first direction X. The sizes d2 of respective first test marks 111a in the first direction are gradually increased or gradually decreased along the arrangement direction of the first direction X. It facilitates measurement of the distortion of the mask in the case that multiple patterns are arranged on the mask, thereby obtaining the quality level of the mask.

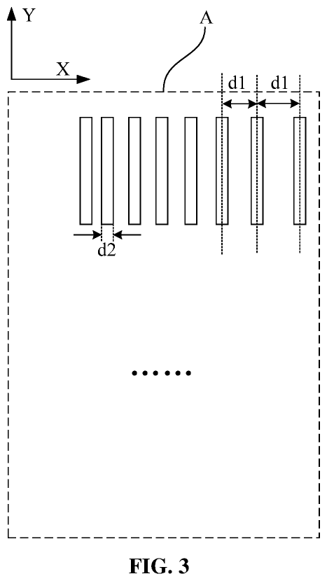

FIG. 3 is another enlarged view of the test area A of the mask of FIG. 1. In some embodiments, the test area A may include the plurality of first test marks 111a sequentially arranged along the first direction X. Each of the first test marks 111a has an identical width d2 along the first direction X. Each two adjacent first test marks 111a is arranged with the spacing d1 between the midlines of the two adjacent first test marks 111a, the spacings d1 between the every two adjacent first test marks 111a are gradually increased or gradually decreased along the first direction X, and each of the midlines extend along the second direction Y perpendicular to the first direction X.

FIG. 2 shows a case in which the spacings d1 are constant and widths d2 of the first test marks are different form one another. Of course, the first test marks 111a may also have an identical width d2 and be sequentially arranged with the different spacing d1 between adjacent first test marks. Specifically, all of first test marks 111a have an identical width d2 along the first direction X. Each two adjacent first test marks 111a is arranged with the spacing between the midlines of the two adjacent first test marks. The spacings between the every two adjacent first test marks along the first direction are gradually increased or gradually decreased, and it is also possible to measure the distortion of the mask in the case that multiple pattern are arranged on the mask, thereby determining the stability of the mask and determining whether the mask is qualified.

It should be noted that, for either the first test marks 111a arranged with an identical spacing d1 and having the different widths d2 or the first test marks 111a having an identical width d2 and arranged with the different spacings d1, it is possible to obtain the distortion of the mask according to the deviation between the actual size and the design size of each of the first test marks 111a in different states, and then it is determined that the mask is unqualified when the distortion degree is large, so as to prevent the problem of the low accuracy of the mask. In the present embodiment, the test area A may include the first test marks 111a arranged with the identical spacing d1 and having the different widths d2 shown in FIG. 2, or may include the first test marks 111a having the identical width d2 and arranged with the different spacings d1 shown in FIG. 3, or may meanwhile include the first test marks 111a arranged with the identical spacing d1 and having the different widths d2 and the first test marks 111a having the identical width d2 and arranged with the different spacings d1, and thus the test accuracy for the test marks 111 is further enhanced, which facilitates the accurate analysis on the quality of the mask.

In some embodiments, test area A includes multiple sets of the first test marks 111a sequentially arranged along the first direction X. In each set of the first test marks 111a, each two adjacent first test marks 111a are arranged with the identical spacing between the midlines of the two adjacent first test marks 111a, each of the first test marks 111a has the identical width d2 along the first direction X, each of the midlines extends along the second direction Y perpendicular to the first direction X. The spacing between the midlines of each two adjacent first test marks 111a in one set of the first test marks 111a is different from the spacing between the midlines of each two adjacent first test marks 111a in another set of the first test marks 111a, and/or the width of each of the first test marks 111a along the first direction X in one set of the first test marks 111a is different from the width of each of the first test marks 111a along the first direction in another set of the first test marks 111a.

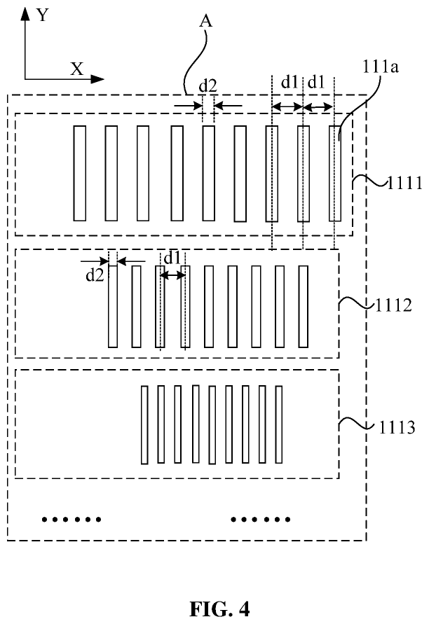

FIG. 4 is another enlarged view of the test area A of the mask of FIG. 1. FIG. 4 shows multiple sets of first test marks 111a, the first test marks 111a in each set of the first test marks 111a are sequentially arranged along the first direction X, and each two adjacent first test marks 111a are arranged with the identical spacing d1 between the midlines of the two adjacent first test marks 111a, and each of the first test marks 111a has the identical width d2 along the first direction X. In addition, the width d2 of each of the first test marks 111a along the first direction X in one set of the first test marks 111a is different from the width d2 of each of the first test marks 111a along the first direction X in another set of the first test marks 111a, and/or the spacing d1 between the midlines of each two adjacent first test marks 111a in one set of the first test marks 111a is different from the spacing d1 between the midlines of each two adjacent first test marks 111a in another set of the first test marks 111a. FIG. 4 shows both of the above cases at the same time. For example, as shown in FIG. 4, multiple sets of the first test marks 111a may be sequentially arranged in the second direction Y perpendicular to the first direction X, to simultaneously measure the effects of an array of the stripe-shaped patterns with different spacing and width on the quality of the mask. Multiple sets of the test marks may be arranged at once and will be called a first set 1111 of the test marks, a second set 1112 of the test marks, a third set 1113 of the test marks, and so on. For the first set 1111 of the test marks, the width d2 of the first test marks 111a is 80 nm and the spacing d1 is 80 nm. For the second set 1112 of the test marks, the width d2 of the first test marks 111a is 100 nm and the spacing d1 is 100 nm. For the third set 1113 of the test marks, the width d2 of the first test marks 111a is 120 nm and the spacing is 120 nm. Similarly, multiple sets of the test marks may be provided to further improve the test of the stability of the mask.

In some embodiments, a shape of each of the first test marks 111a may be at least one of a stripe shape, a trapezoidal shape, or an L-shape. FIGS. 2 and 3 show only the first test marks 111a in the stripe shape. In the embodiment, each of the first test marks 111a may be in the trapezoidal shape, the L-shape or other regular or irregular shape, which is not limited in the embodiment.

In some embodiments, with reference to FIG. 2, the shape of each of the first test marks 111a may be the stripe shape. A length d3 of the stripe shape along the second direction Y is greater than a width d2 of the stripe shape along the first direction X. The length of each of the first test marks 111a ranges from 3 μm to 5 μm. The width of each of the first test marks 111a along the first direction X ranges from 80 nm to 1200 nm. The spacing between the midlines of each two adjacent first test marks 111a ranges from 80 nm to 1200 nm.

As shown in FIGS. 2 and 3, the shape of each of the first test marks 111a may be the stripe shape. In the embodiment, in order to prevent each of the first test marks 111a from affecting an exposure process and to avoid forming the exposure pattern, it is necessary to control the size of each of the first test marks 111a within a certain range. In the embodiment, the stripe shape extends along the direction of the second direction Y. A width direction is the first direction X. The length d3 ranges from 3 μm to 5 μm, the width ranges from 80 nm to 1200 nm, and the spacing d1 between the midlines of each two adjacent stripe shape first test marks 111a ranges from 80 nm to 1200 nm. In addition, along the second direction Y, the present example may further include multiple rows (for example, seven rows or eight rows) of the first test marks 111a arranged along the first direction X. The accuracy of the quality measurement is further enhanced. As shown in FIG. 4, in the second direction Y, the example includes multiple rows of the first test marks 111a arranged in the first direction X in which the different rows have different widths d2 and/or different spaces d1 between the adjacent midlines. For example, 14 rows of the first test marks 111a may be provided. In the second direction Y, for any row of the first test marks 111a arranged along the first direction X from top to bottom have a width d2 identical with the spacing d1 between the adjacent midlines. The widths d2 of the respective rows of the first test marks 111a and the midlines may be 80 nm, 100 nm, 120 nm, 160 nm, 200 nm, 240 nm, 280 nm, 320 nm, 400 nm, 520 nm, 640 nm, 800 nm, 1000 nm and 1200 nm, respectively. In the rows along the second direction Y, the first test marks 111a arranged along the first direction X may also include multiple sets of the first test marks 111a. For example, a row of the first test marks 111a arranged along the first direction X may include two sets of the first test marks 111a, and the width d2 in one set of the first test marks 111a is different from the width d2 in another set of the first test marks 111a, and/or the spacing d1 between the adjacent midlines in one set of the first test marks 111a is different from the spacing d1 between the adjacent midlines in another set of the first test marks 111a, so that seven rows of the first test marks 111a may include fourteen different widths d2 and/or spacings d1 between the adjacent midlines.

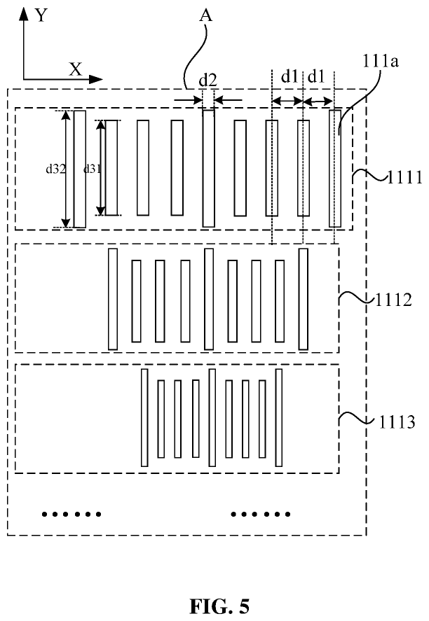

FIG. 5 is another enlarged view of the test area A of the mask of FIG. 1. In some embodiments, the multiple first test marks 111a includes at least one first test mark 111a having a first length d31 along the second direction Y, and at least one first test mark 111a having a second length d32 along the second direction Y greater than the first length d31. A preset number of the first test marks 111a having the first length d31 is arranged between the each two adjacent first test marks 111a having the second length d32. In the present embodiment, each first test mark 111a having the second length d32 may be alternate with preset number of the first test marks 111a having the first length d31. For example, each first test mark 111a having the second length d32 may be alternate with every three first test marks 111a having the first length d31. The arrangement of first test marks 111a of different lengths may facilitate calculation of the average value of the spacings d1. For example, referring to FIG. 5, the total spacing between the midlines of the two adjacent first test marks 111a having the second length d32 can be measured, and there are four spacings d1 therebetween. The average spacing d1 can be obtained by dividing the total spacing by four, without measuring the spacings d1 one by one. The measurement process is simple, and the measurement progress is accelerated.

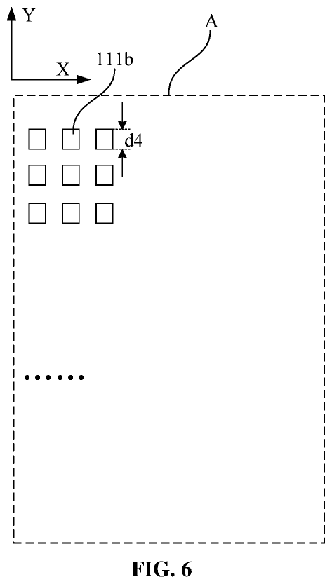

FIG. 6 is another enlarged view of the test area A of the mask of FIG. 1. In some embodiments, the test area A may include multiple second test marks 111b arranged in an array. Each two adjacent second test marks 111b are arranged with the identical spacing d4 between centers of the two adjacent second test marks.

In this embodiment, second test marks 111b are arranged in the array, and the second test marks 111b may be uniformly arranged, that is, in a row direction and a column direction of the array, the spacings d4 between the center of each second test mark 111b and the center of the other adjacent second test marks 111b are identical, and a distances between the second test marks 111b and the adjacent second test marks 111b are identical. In the present embodiment, the second test marks 111b of one same size may be provided, or the second test marks 111b of multiple sizes may be provided, to measure the accuracy of the mask.

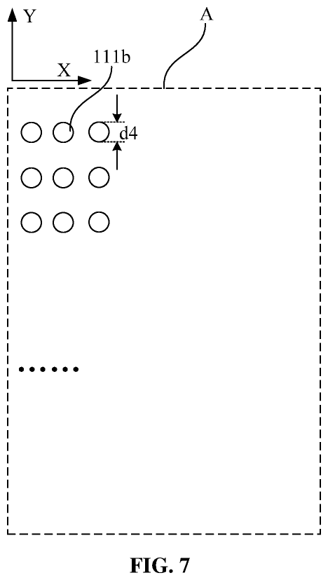

In some embodiments, the second test marks 111b may be in the shape of at least one of a round shape, a square shape, a regular pentagon shape or a regular hexagon shape. As shown in FIG. 6, FIG. 6 shows a case where the second test marks 111b are in the shape of the square shape. FIG. 7 is an enlarged view of the test area A of the mask of FIG. 1. As shown in FIG. 7, FIG. 7 shows a case where the second test marks 111b are in shape of the circle. In addition, the second test marks 111b may also be in the shape of the regular pentagon shape, the regular hexagon shape, or the like, which is not limited in this embodiment. In some embodiments, the second test marks 111b are in the shape like a hole, so that the distortion rate of the mask provided with the hole pattern can be measured, thereby the accuracy of the mask is measured. In some embodiments, a radial dimension d4 of the second test marks 111b ranges from 100 nm to 1000 nm, to avoid the second test marks 111b from forming the exposed pattern.

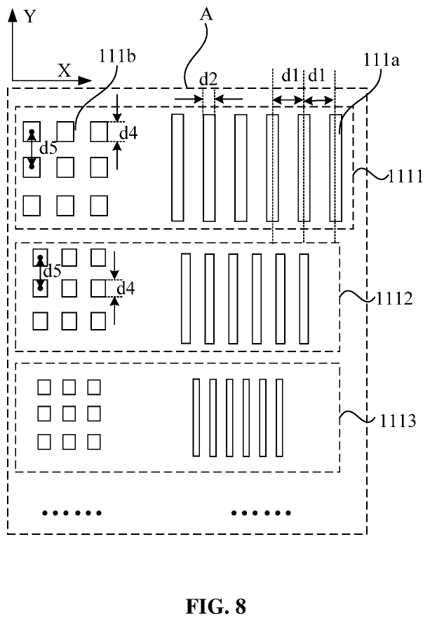

As shown in FIG. 8, FIG. 8 is another enlarged view of the test area A of the mask of FIG. 1. In some embodiments, the test area A includes multiple sets of the second test marks 111b arranged in arrays. In each set of the second test marks 111b, each two adjacent second test marks 111b are arranged with the identical spacing d5 between centers of two adjacent second marks, and all of the second test marks have an identical radial dimension d4. The spacing d5 between the centers of two adjacent second test marks 111b in one set of the second test marks 111b is different from the spacing d5 between the centers of two adjacent second test marks in another set of the second test marks 111b, and/or the radial dimensions d4 of each of the second test marks 111b in one set of the second test marks 111b is different from the radial dimension d4 of each of the second test marks 111b in another set of the second test marks 111b. FIG. 8 shows a case where the radial dimension d4 of each of the second test marks 111b in one set of the second test marks 111b is different from the radial dimension d4 of each of the second test marks 111b in the adjacent set, and the spacing d5 between the centers of two adjacent second test marks 111b in one set of the second test marks 111b is different from the spacing d5 between the centers of two adjacent second test marks 111b in the adjacent set. For example, as shown in FIG. 8, in the second direction Y perpendicular to the first direction X, multiple sets of the second test marks 111b may be sequentially arranged to simultaneously measure the effect of the array of the stripe shape patterns having different spacings and widths on the quality of the mask. Multiple sets of the test marks may be arranged at once and will be called a first set 1111 of the test marks, a second set 1112 of the test marks, a third set 1113 of the test marks, and so on. For the first set 1111 of test marks, the radial dimension d4 of the second test marks 111b is 100 nm. For the second set 1112 of the test marks, the radial dimension d4 of the second test marks 111b is 150 nm. For the third set 1113 of test marks, the radial dimension d4 of the second test marks 111b is 200 nm. Similarly, multiple sets of the test marks may be provided to further improve the test of the stability of the mask. In some embodiments, the spacing d5, between the center of a second test mark 111b in one set and the center of an adjacent second test mark 111b in an adjacent set, ranges from 320 nm to 840 nm.

Based on the above-described embodiment, a specific structural example of the mask is provided. With reference to FIG. 8, the mask region A is provided with the first test mark 111a and the second test mark 111b at the same time. As shown in FIG. 8, multiple sets of test marks may be sequentially arranged perpendicular to the first direction X to simultaneously measure the effect of the stripe shape pattern and the hole pattern on the quality of the mask. Multiple sets of the test marks may be arranged at once and will be called a first set 1111 of the test marks, a second set 1112 of the test marks, a third set 1113 of the test marks, and so on. For the first set 1111 of the test marks, the width d2 of the first test marks 111a is 80 nm, the spacing d1 is 80 nm, and the radial dimension d4 of the second test marks 111b is 100 nm. For the second set 1112 of the test marks, the width d2 of the first test mark 111a is 100 nm, the spacing d1 is 100 nm, and the radial dimension d4 of the second test mark 111b is 150 nm. For the third set 1113 of the test marks, the line width d2 of the first test mark 111a is 120 nm, the spacing d1 is 120 nm, and the radial dimension d4 of the second test mark 111b is 200 nm. Similarly, multiple sets of the test marks may be provided to further improve the test of the stability of the mask.

In some embodiments, the test mark is a pattern pervious to light or a pattern impenetrable to light. In the present embodiment, either the first test marks or the second test marks may be the pattern pervious to light or the pattern impenetrable to light, as long as the quality evaluation can be performed by hollow pattern in entire test area A, and the specific form of the test marks are not limited in the present embodiment.

Based on the same concept, the disclosed embodiment further provides a method for testing a quality of the mask which is applicable to mask provided in the above embodiments. FIG. 9 is a schematic flow chart of a method for testing the quality of the mask according to the embodiment of the present disclosure. As shown in FIG. 9, the method of the embodiment of the present disclosure includes the following steps:

At block S110, the actual size of each of the test marks in the test area in the region other than mask exposure region is measured.

At block S120, the deviation between the actual size and the design size of each of the test marks is obtained.

At block S130, in response to the deviation greater than an allowable error threshold value, it is determined that the mask is unqualified; in response to the deviation less than the allowable error threshold value, it is determined that the mask is qualified.

The allowable error threshold value is a maximum allowable range of the deviation between the actual size and the design size of the test mark, which ensures that the mask does not affect the accuracy of the mask. When the deviation is greater than the allowable error threshold value, the mask pattern may be significantly distorted, which will affect the accuracy of the mask. Therefore, by comparing the deviation with the allowable error threshold value, it can be determined whether the mask is qualified.

In the embodiment of the present disclosure, the mask includes the mask exposure region and the region other than mask exposure region, the mask exposure region is formed with the mask pattern for forming the exposure pattern on the wafer, and the region other than mask exposure region is provided with the test area for testing the quality of the mask. Specifically, the test area is provided with at least one test mark, and each of the test marks does not form the exposure pattern on the wafer, and is only used for testing the quality problem due the material, the manufacturing process, or other factors of the mask through the distortion of the test marks during the forming process, and the distortion degree can be known by comparing the actual size and the design size of the test marks. The mask and the method for testing the quality of the mask provided by the embodiments of the present disclosure can be used to know the manufacturing quality of the mask, for example, whether the mask is qualified, thereby the stability of the mask is enhanced, the stability of the mask pattern is further ensured, the accuracy of the mask is enhanced, the yield of the wafer or even the final product is enhanced, and the risk of remanufacturing of the mask is reduced, and the cost waste in the photolithographic process is prevented.

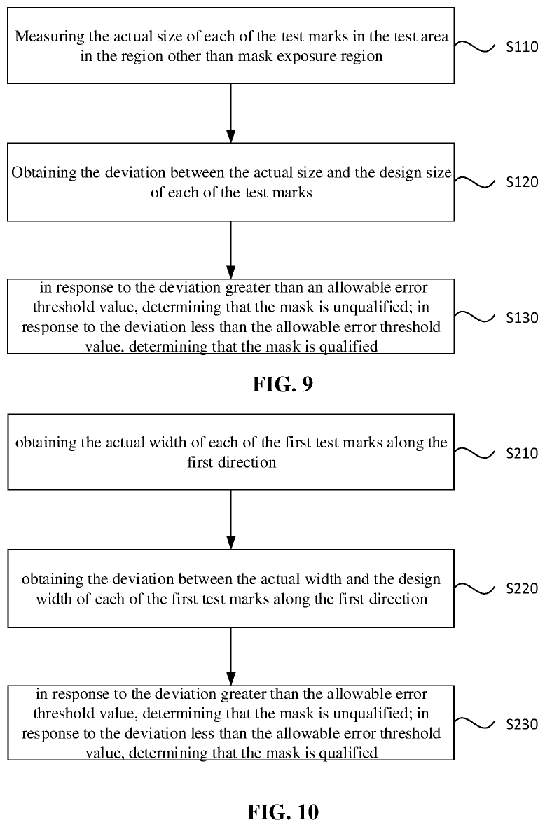

In some embodiments, the test area may include multiple first test marks sequentially arranged along a first direction. As shown in FIG. 10, FIG. 10 is a schematic flow chart of another method for testing the quality of the mask according to the embodiment of the present disclosure. The method of the embodiment of the present disclosure includes the following steps:

At block S210, the actual width of each of the first test marks along the first direction is obtained.

In the present embodiment, when the test area includes the first test marks sequentially arranged, the measurement of the actual size of each of the test marks of the test area of the mask non-exposure area specifically includes: obtaining the actual width of each of the first test marks along the first direction.

In some embodiments, each two adjacent first test marks are arranged with the identical spacing between midlines of the two adjacent first test marks, each of the midlines extends along the second direction perpendicular to the first direction. The widths of first test marks in the first direction are gradually increased or gradually decreased along the first direction.

Alternatively, each of the first test marks has the identical width along the first direction. The spacings, between midlines of adjacent first test marks along the first direction, are gradually increased or gradually decreased along the first direction, each of the midlines extends along the second direction perpendicular to the first direction.

At block S220, the deviation between the actual width and the design width of each of the first test marks along the first direction is obtained.

In the present embodiment, obtaining the deviation between the actual size and the design size of each of the test marks specifically includes: obtaining the deviation between the actual width and the design width of each of the first test marks along the first direction.

At block S230, in response to the deviation greater than the allowable error threshold value, it is determined that the mask is unqualified; in response to the deviation less than the allowable error threshold value, it is determined that the mask is qualified.

In the present embodiment, as the test mark includes the first test mark, the actual size of the test mark along the first direction is obtained, and the stability of the mask is determined from the deviation between the actual width and the design width, thereby the accurate measurement of the quality of the mask is improved.

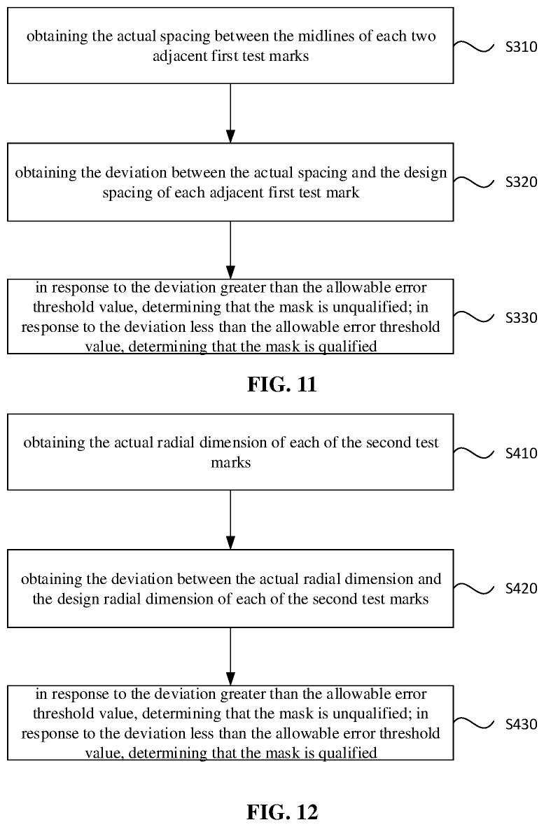

In some embodiments, the test area may include multiple first test marks sequentially arranged along the first direction. As shown in FIG. 11, FIG. 11 is a schematic flow chart of another method for testing the quality of the mask according to an embodiment of the present disclosure. The method of the embodiment includes the following steps:

At block S310: the actual spacing between the midlines of each two adjacent first test marks is obtained.

In some embodiments, each two adjacent first test marks are arranged with the identical spacing between midlines of the two adjacent first test marks, each of the midlines extends along the second direction perpendicular to the first direction. The widths of first test marks in the first direction are gradually increased or gradually decreased along the first direction.

Alternatively, each of the first test marks has the identical width along the first direction. The spacings, between midlines of each two adjacent first test marks along the first direction, are gradually increased or gradually decreased along the first direction, each of the midlines extends along the second direction perpendicular to the first direction.

Based on the above embodiment, the multiple first test marks includes at least one first test mark having a first length along the second direction, and at least one first test mark having a second length along the second direction greater than the first length. A preset number of the first test marks having the first length is arranged between the each two adjacent first test marks 111a having the second length. Obtaining the actual spacing between the midlines of each two adjacent first test marks includes: obtaining a total spacing between the midlines of each two adjacent first test marks having the second lengths; calculating the average value based on the preset number and the total spacing. The average value is considered as the actual spacing between the midlines of each two adjacent first test marks.

According to the present embodiment, each first test mark having the second length may be alternate with preset number of the first test marks having the first length. The first test mark having different lengths may facilitate calculation of the average value of the spacings. For example, the total spacing between the midlines of the two adjacent first test marks having the second length can be measured, and there are preset number of the first test marks therebetween. The calculated average value of the spacings can be obtained by dividing the total spacing by the preset number. The calculated average value is considered as the actual spacing between the midlines of each two adjacent first test marks, so that it is not necessary to measure the above-mentioned actual spacing one by one. The measurement process is simple and the measurement progress is accelerated.

At block S320, the deviation between the actual spacing and the design spacing between adjacent first test marks is obtained.

In the present embodiment, measuring the actual size of the test marks of the test area of the region other than mask exposure region and obtaining the deviation between the actual size and the design size of the test marks specifically include the above S310 and S320.

At block S330, when the deviation is greater than the allowable error threshold value, determining that the mask is unqualified. When the deviation is less than the allowable error threshold value, determining that the mask is qualified.

The present embodiment provides another implementation method for quality measurement of the test marks, in which the actual spacing between the midlines of each two adjacent test marks is measured, and the stability of the mask is determined from the deviation between the actual spacing and the design spacing, and the accurate measurement of the quality of the mask is improved.

In some embodiments, the test area includes the second test marks arranged in array, as shown in FIG. 12. FIG. 12 is a schematic flow chart of another method for testing the quality of the mask according to an embodiment of the present disclosure, the method of the present embodiment includes the following steps:

At block S410, an actual radial dimension of each of the second test marks is obtained.

In this embodiment, when the test area includes the second test marks arranged in array, the measurement of the actual size of the test marks of the test area of the region other than mask exposure region specifically includes: obtaining the actual radial size of each of the second test marks.

In some embodiments, each two adjacent second test marks is arranged with the identical spacing between midlines of the two adjacent first test marks. The second test marks are in the shape of at least one of a round shape, a square shape, a regular pentagon shape or a regular hexagon shape.

At block S420, the deviation between the actual radial dimension and the design radial dimension of each of the second test marks is obtained.

In the present embodiment, obtaining the deviation between the actual size and the design size of each of the test marks specifically includes: obtaining the deviation between the actual radial size and the design radial size of each of the second test marks.

At block S430, in response to the deviation greater than the allowable error threshold value, it is determined that the mask is unqualified; in response to the deviation less than the allowable error threshold value, it is determined that the mask is qualified.

According to the present embodiment, when the test mark includes the second test mark, the radial dimension of the hole pattern is obtained, and the stability of the mask is determined from the deviation between the actual radial dimension and the design radial dimension, thereby the accurate measurement of the quality of the mask is improved.

It should be note that the foregoing is merely a preferred embodiment of the present disclosure and the principles of the techniques employed. It will be understood by those skilled in the art that the present disclosure is not limited to the specific embodiments described herein, and that various obvious changes, modifications, and substitutions can be made by those skilled in the art without departing from the scope of the present disclosure. Thus, while the present disclosure has been described in more detail by the above embodiments, the present disclosure is not limited to the above embodiments, and many other equivalent embodiments may be included without departing from the spirit of the present disclosure, the scope of which is determined by the scope of the appended claims.

1. A mask, comprising a mask exposure region and a region other than mask exposure region;
the mask exposure region is provided with a mask pattern; and
the region other than mask exposure region is provided with a test area, the test area comprising at least one test mark, a quality of the mask is determined from a deviation between a design size and an actual size of each test mark.

2. The mask according to claim 1, wherein the test area comprises a plurality of first test marks sequentially arranged along a first direction, each two adjacent first test marks being arranged with an identical spacing between midlines of the two adjacent first test marks, each of the midlines extending along a second direction perpendicular to the first direction; and
widths of the first test marks in the first direction are gradually increased or gradually decreased along the first direction.

3. The mask according to claim 1, wherein the test area comprises a plurality of first test marks sequentially arranged along a first direction, each of the first test marks has an identical width along the first direction; and
each two adjacent first test marks being arranged with a spacing between midlines of the two adjacent first test marks, the spacings between the each two adjacent first test marks are gradually increased or gradually decreased along the first direction, each of the midlines extending along a second direction perpendicular to the first direction.

4. The mask according to claim 1, wherein the test area comprises multiple sets of first test marks sequentially arranged along a first direction; in each set of the first test marks, each two adjacent first test marks being arranged with an identical spacing between midlines of the two adjacent first test marks, each of the first test marks has an identical width along the first direction, each of the midlines extending along a second direction perpendicular to the first direction; and
the spacing between the midlines of each two adjacent first test marks in one set of the first test marks is different from the spacing between the midlines of each two adjacent first test marks in another set of the first test marks.

5. The mask according to claim 4, wherein the width of each of the first test marks along the first direction in one set of the first test marks is different from the width of each of the first test marks along the first direction in another set of the first test marks.

6. The mask according to claim 1, wherein the test area comprises multiple sets of first test marks sequentially arranged along a first direction; in each set of the first test marks, each two adjacent first test marks being arranged with an identical spacing between midlines of the two adjacent first test marks, each of the first test marks has an identical width along the first direction, each of the midlines extending along a second direction perpendicular to the first direction; and
the width of each of the first test marks along the first direction in one set of the first test marks is different from the width of each of the first test marks along the first direction in another set of the first test marks.

7. The mask according to claim 2, wherein a shape of each of the first test marks is at least one of a stripe shape, a trapezoidal shape or an L-shape.

8. The mask according to claim 7, wherein the shape of each of the first test marks is stripe shape, a length of the stripe shape along the second direction being greater than a width of the stripe shape along the first direction;
the length of each of the first test marks ranges from 3 μm to 5 μm;
the width of each of the first test marks along the first direction ranges from 80 nm to 1200 nm; and
the spacing between the midlines of each two adjacent first test marks ranges from 80 nm to 1200 nm.

9. The mask according to claim 8, wherein the plurality of first test marks comprises at least one first test mark having a first length along the second direction, and at least one first test mark having a second length along the second direction greater than the first length; and
a preset number of the first test marks having the first length is arranged between each two adjacent first test marks having the second length.

10. The mask according to claim 1, wherein the test area comprises a plurality of second test marks arranged in an array; and each two adjacent second test marks being arranged with an identical spacing between centers of the two adjacent second test marks.

11. The mask according to claim 10, wherein
the second test marks are in a shape of at least one of a round shape, a square shape, a regular pentagon shape or a regular hexagon shape.

12. The mask according to claim 10, wherein the test area comprises the multiple sets of the second test marks arranged in arrays; in each set of the second test marks, each two adjacent second test marks being arranged with an identical spacing and an identical radial dimension between centers of two adjacent second test marks; and
the spacing between the centers of each two adjacent second test marks in one set of the second test marks is different form the spacing between the centers of each of the two adjacent second test marks in another set of the second test marks.

13. The mask according to claim 12, wherein the radial dimension of each of the second test marks in one set of the second test marks is different from the radial dimension of each of the second test marks in another set of the second test marks.

14. The mask according to claim 10, wherein the test area comprises the multiple sets of the second test marks arranged in arrays; in each set of the second test marks, each two adjacent second test marks being arranged with an identical spacing and an identical radial dimension between centers of two adjacent second test marks; and
the radial dimension of each of the second test marks in one set of the second test marks is different from the radial dimension of each of the second test marks in another set of the second test marks.

15. The mask according to claim 1, wherein the test mark is a pattern pervious to light or a pattern impenetrable to light.

16. A method for testing a quality of a mask comprising a mask exposure region and a region other than mask exposure region, the mask exposure region being provided with a mask pattern, the region other than mask exposure region being provided with a test area, the test area comprising at least one test mark,
wherein, the method comprises:
measuring an actual size of the test mark in a test area in a region other than a mask exposure region;
obtaining a deviation between the actual size and a design size of the test mark;
in response to the deviation greater than an allowable error threshold value, determining that the mask is unqualified; and
in response to the deviation less than the allowable error threshold value, determining that the mask is qualified.

17. The method for testing the quality of the mask according to claim 16, wherein the test area comprises a plurality of first test marks sequentially arranged along a first direction;
measuring the actual size of each of the test marks in the test area in the region other than mask exposure region, and obtaining the deviation between the actual size and the design size of each of the test marks, comprising:
obtaining an actual width of each of the first test marks along a first direction; and
obtaining the deviation between the actual width and a design width of each of the first test marks along the first direction.

18. The method for testing the quality of the mask according to claim 16, wherein the test area comprises a plurality of first test marks sequentially arranged along a first direction;
measuring the actual size of each of the first test marks of the test area of the region other than mask exposure region; obtaining the deviation between the actual size and the design size of each of the first test marks, comprises:
obtaining an actual spacing between midlines of each two adjacent first test marks; and
obtaining the deviation between the actual spacing and a design spacing of each adjacent first test mark.

19. The method for testing the quality of the mask according to claim 18, wherein the plurality of first test marks comprises at least one first test mark having a first length along a second direction, and at least one first test mark having a second length along the second direction greater than the first length; a preset number of the first test marks having the first length is arranged between the each two adjacent first test marks having the second length;
obtaining the actual spacing between the midlines of each two adjacent first test marks, comprises:
obtaining a total spacing between the midlines of each two adjacent first test marks having the second length; and
calculating an average value based on the preset number and the total spacing, wherein the average value is adopted as the actual spacing between the midlines of each two adjacent first test marks.

20. The method for testing the quality of the mask according to claim 16, wherein the test area comprises a plurality of second test marks arranged in an array;
measuring the actual size of each of the second test marks of the test area of the region other than mask exposure region and obtaining the deviation between the actual size and the design size of each of the second test marks, comprises:
obtaining an actual radial dimension of each of the second test marks; and
obtaining a deviation between the actual radial dimension and a design radial dimension of each of the second test marks.
